(19) United States
(12) Patent Application Publication
(10) Pub. No.: US 2016/0355925 A1
(43) Pub. Date: Dec. 8, 2016

(54) EVAPORATION SOURCE DEVICE AND EVAPORATION APPARATUS

(71) Applicant: BOE TECHNOLOGY GROUP CO., LTD., Beijing (CN)

(72) Inventor: Shibo JIAO, Beijing (CN)

(73) Assignee: BOE TECHNOLOGY GROUP CO., LTD., Beijing (CN)

(21) Appl. No.: 15/138,430

(22) Filed: Apr. 26, 2016

(30) Foreign Application Priority Data
Jun. 3, 2015 (CN) 201510300073.7

(51) Int. Cl. C23C 14/24

(52) U.S. Cl. CPC C23C 14/243

(57) ABSTRACT

Embodiments of the present invention provide an evaporation source device and an evaporation apparatus. The evaporation source device includes: a crucible having an opening, configured for accommodating a material; a stirring unit, configured for stirring the material in the crucible; and a driving unit, configured for driving the stirring unit to rotate.

### TECHNICAL FIELD

Embodiments of the present invention relate to an evaporation source device and an evaporation apparatus.

### BACKGROUND

In recent years, an Organic Light Emitting Display (OLED), as a new type of flat panel display, has gradually attracted more attention. The OLED becomes a next generation of display technology that may replace a liquid crystal display, due to its characteristics such as self-illumination, high brightness, high resolution, wide viewing angle, fast response, low power consumption and flexibility and so on.

An evaporation apparatus is an experiment and production device in a thin film fabrication field, and is widely used for fabricating an organic photovoltaic device such as an Organic Light-Emitting Diode (OLED), an Organic Photovoltaic Cell (OPV), an Organic Field Effect Transistor (OFET).

In an OLED display device, a carrier transport layer and an organic light-emitting layer of an organic light-Emitting diode are fabricated by evaporating organic material. Nowadays, evaporation sources of an OLED evaporation apparatus have a dot evaporation source and a linear evaporation source. In the evaporation source device, organic evaporation materials being evaporated are mainly divided into two types: one is a sublimation type organic material, and the other is melting type organic material. Wherein, the sublimation type organic material, when heated, is directly sublimated into a gas state and then cooled on a substrate to form an organic film layer; while the melting type organic material, when heated, is melt into a liquid state and then become a gas state, and finally cooled on a substrate to form an organic film layer.

As shown in FIG. 1, FIG. 1 is a structural schematic diagram of an existing evaporation source device. The evaporation source device includes a crucible 01 for accommodating an organic material; the crucible 01 is heated, to evaporate the organic material in the crucible 01. Because only crucible walls surrounding the crucible 01 are heated when heating the crucible 01, as for the organic material in the crucible slot of the crucible 01, it has a poor thermal conductivity, and a thermal transmission path is relatively long, thus easy to cause uneven thermal transfer. In particular for a large-sized evaporation source, a phenomenon of uneven distribution of temperature is more obvious, thus resulting in problems of insufficient stability of a vaporizing rate of the evaporation of the organic material and reducing product yield and so on.

As shown in FIG. 1, as for an sublimation type OLED organic material, in a process of evaporation, the organic material close to crucible walls in the crucible may be sublimated early because of being heated at first, while the organic material in a center part may gradually form an erect island-like structure 02 because of being heated slowly. In order to maintain a stable vaporizing rate, the evaporation source may constantly increase temperature. Therefore, the organic material in the crucible in contact with a bottom of the crucible may be overheated, resulting in decomposition or degradation of the organic material, leading to waste of material and pollution, even affecting performance of the OLED device.

### SUMMARY

An embodiment of the present invention provides an evaporation source device including: a crucible having an opening, configured for accommodating a material; a stirring unit, configured for stirring the material in the crucible; and a driving unit, configured for driving the stirring unit to rotate.

Another embodiment of the present invention provides an evaporation apparatus including the above evaporation source device.

### BRIEF DESCRIPTION OF THE DRAWINGS

In order to clearly illustrate the technical solution of the embodiments of the present invention, the drawings of the embodiments will be briefly described in the following; it is obvious that the described drawings are only related to some embodiments of the present invention and thus are not limitative of the present invention.

FIG. 1 is a structural schematic diagram of an existing evaporation source device;

FIG. 2 is a first structural schematic diagram of an evaporation source device provided by an embodiment of the present invention;

FIG. 3 is a second structural schematic diagram of an evaporation source device provided by an embodiment of the present invention;

FIG. 4 is a third structural schematic diagram of an evaporation source device provided by an embodiment of the present invention; and

FIG. 5 is a structural schematic diagram of an evaporation apparatus provided by an embodiment of the present invention.

### DETAILED DESCRIPTION

In order to make objects, technical details and advantages of the embodiments of the present invention apparent, the technical solutions of the embodiment will be described in a clearly and fully understandable way in connection with the drawings related to the embodiments of the present invention. It is obvious that the described embodiments are just a part but not all of the embodiments of the present invention. Based on the described embodiments herein, those skilled in the art can obtain other embodiment(s), without any inventive work, which should be within the scope of the present invention.

Unless otherwise specified, the technical terms or scientific terms here should be of general meanings as understood by those ordinarily skilled in the art. In the specification and claims of the present invention of the patent application, words such as “first”, “second” and the like do not denote any order, quantity, or importance, but rather are used for distinguishing different components. Words such as “include” or “comprise” and the like denote that elements or objects appearing before the words of “include” or “comprise” cover the elements or the objects enumerated after the words of “include” or “comprise” or equivalents thereof, not exclusive of other elements or objects. “Connected” or “coupled” or similar words are not limited to physical or mechanical connection, and may comprise electrical connection, either direct or indirect connection. Words such as “up”, “down”, “left”, “right”, “horizontal”, “vertical” and the like are only used for expressing relative positional relationship, when the absolute position of a described object is changed, the relative positional relationship may also be correspondingly changed.

Embodiments of the present invention provide an evaporation source device and an evaporation apparatus, which can improve uniformity in heating a material, further increase a material deposition yield, and improve performance of a display device.

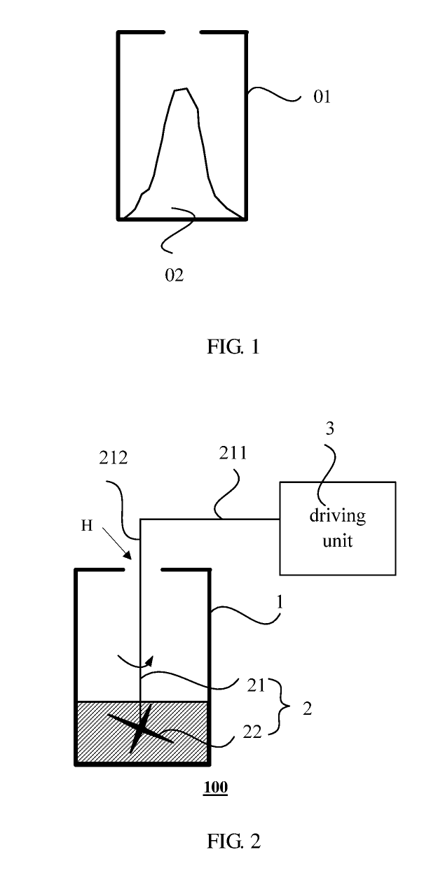

FIG. 2 is a first structural schematic diagram of an evaporation source device provided by an embodiment of the present invention. As shown in FIG. 2, an evaporation source device 100 provided by the embodiment of the present invention, comprises:
a crucible 1 having an opening, for accommodating a material;
a stirring unit 2, located in the crucible 1, for stirring the material in the crucible 1;
a driving unit 3, for driving the stirring unit 2 to rotate.

In the evaporation source device provided by the embodiment of the present invention, the material in the crucible 1 is stirred by the arranged stirring unit 2, so that a contact area between the material and side walls of the crucible 1 keeps relatively large, reducing a case where part of the material is overheated, thus reducing a phenomenon of decomposition or degradation of the material.

Therefore, an evaporation source device provided by the embodiment of the present invention can improve uniformity of heating a material, further increase a Material deposition yield, and improve performance of a display device.

As shown in FIG. 2, the stirring unit 2 includes: a connecting rod 21 and one or more blades 22. An end of the connecting rod 21 is connected with the driving unit 3, and the other end is fixedly connected with the blade(s) 22. For example, the end of the connecting rod 21 is in rotatable connection with the driving unit 3. In the embodiment, for example, the number of the one or more blades 22 may be, for example, 2. In another example, the number of the one or more blades 22 may be, for example, greater than 2.

In an optional implementation mode, as shown in FIG. 2, the stirring unit 2 includes the connecting rod 21 and two blades 22, and an end of the connecting rod 21 is in rotatable connection with the driving unit 3, and the other end of the connecting rod 21 is fixedly connected with the two blades 22. The connecting rod 21 may be of a lot of shapes. Optionally, as shown in FIG. 2, the connecting rod 21 includes two sub connecting rods, i.e., a vertical rod 212 and a horizontal rod 211. The two blades 22 are configured to intersect with each other and be fixedly connected with the vertical rod 212 of the connecting rod 21. The two blades 22 can be driven by the connecting rod 21 to respectively rotate around an axis of the vertical rod 212 of the connecting rod 21. In the embodiment shown in FIG. 2, the axis of the vertical rod 212 of the connecting rod 21 coincides with an axis of the crucible 1. The axis of the crucible 1 is in the middle of the crucible 1. In this case, in order to fully stir the material in the crucible, the blade 22 can be designed to be relatively large, so that the material close to inner walls of the crucible may be fully stirred. The number of the blades 22 may be determined by those skilled in the art according to actual needs. In another embodiment, a sub connecting rod 212 fixedly connected with the two blades 22 may be in a non-straightline shape.

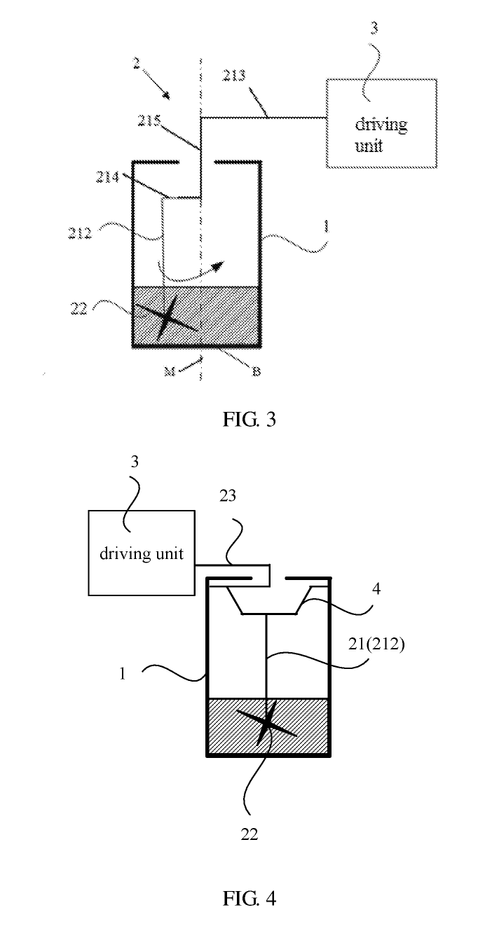

FIG. 3 is a second structural schematic diagram of an evaporation source device provided by an embodiment of the present invention. As shown in FIG. 3, the stirring unit 2 includes: a connecting rod 21 and two blades 22. An end of the connecting rod 21 is in rotatable connection with the driving unit 3, and the other end of the connecting rod 21 is fixedly connected with the two blades 22. The connecting rod 21 includes a vertical rod 212 fixedly connected with the two blades 22. In the embodiment shown in FIG. 3, an axis of the vertical rod 212 does not coincide with the axis of the crucible 1. The two blades 22, together with the vertical rod 212, rotate around a rotation axis M, shown by arrows in FIG. 3. For example, the rotation axis M intersects with a bottom B of the crucible 1 and passes through an opening H of the crucible. The rotation axis M does not intersect with the vertical rod 212. In an example, the rotation axis M is the axis of the crucible 1. As shown in FIG. 3, in addition to the vertical rod 212, the connecting rod 21 further includes horizontal rods 213 and 214, and a vertical rod 215. The shape of the connecting rod 21 is not limited to the shape shown in FIG. 3, when designing such stirring unit 2, the blades 22 may be designed to be relatively small, to prevent the inner walls of the crucible from damages caused by hitting the blade 22 on the inner walls of the crucible when rotating, and the number of the blades may be determined by those skilled in the art according to actual needs. In order to ensure that the vertical rod 212 and the two blades 22 can rotate around the axis M, the horizontal rod 213 is connected with the driving unit 3, so that the horizontal rod 213 can rotate around an axis thereof; the horizontal rod 213 and the vertical rod 215 may be connected with each other through a transmission member such as a set of gear, so that the vertical rod 215 can be driven by the horizontal rod 213 to rotate around an axis of the vertical rod 215; and the axis of the vertical rod 215 coincides with the axis of the crucible. The vertical rod 215, for example, is fixedly connected with the horizontal rod 214, and the horizontal rod 214, for example, is fixedly connected with the vertical rod 212. In addition, the vertical rod 212 may be one rod, or has a plurality of rods in rotatable connection with one another. The vertical rod 212 may further be in a non-straightline shape.

The shapes of the above blade may be tree-like, and strip-like, and so on.

In addition, FIG. 4 is a third structural schematic diagram of an evaporation source device provided by an embodiment of the present invention. As shown in FIG. 4, the evaporation source device further comprises: a shielding net 4, arranged at the opening end of the crucible 1. The shielding net 4 is configured for preventing the material from configured for preventing the material from spilled from the opening H of the crucible 1. The shielding net 4 may rotate together with the stirring unit 2, or may not.

In an example, the shielding net 4 does not rotate together with the stirring unit 2. The shielding net 4 is for example stuck in the crucible. The driving unit is connected with the connecting rod through a transmission rod. A through hole for allowing the connecting rod or the transmission rod to pass therethrough is provided on a bottom of the shielding net.

In another example, the shielding net 4 rotates together with the stirring unit 2. The stirring unit 2 includes: a transmission rod 23, and an end of the transmission rod 23 is connected with the driving unit 3, and the other end of the transmission rod 23 is fixedly connected with a side wall of the shielding net 4. The end of the connecting rod 21 is connected with a bottom of the shielding net 4. In the embodiment, the connecting rod 21, for example, only includes the vertical rod 212. When the stirring unit 2 rotates, the shielding net 4 also rotates. In order to prevent the shielding net 4 from hitting inner walls of the crucible 1 when rotating, without affecting a shielding effect of the shielding net 4 at the same time, an area of the shielding net 4 may be slightly less than an cross-sectional area of the opening end of the crucible. For example, the lateral dimension of the shielding mesh 4 is slightly smaller than the lateral inner diameter of the opening end of the crucible. The specific sizes may be determined by those skilled in the art according to actual needs. The transmission rod 23 may be connected with the shielding net by welding or a blot.

Of course, the connecting structure between the shielding net and the blade as well as the driving unit is not limited to what is shown in FIG. 4, and other shapes and structures may also be used, which will not be described respectively here.

The above shielding net 4 may be made of a metal material.

In the stirring unit of the structures described above, the two blades 22 are connected with the connecting rod 21 by welding or a blot.

Due to high temperature of the material in the crucible, in order to prevent the material in the crucible from being affected by the blades and the connecting rod, the two blades and at least a part of the connecting rod (e.g., the vertical rod 212) are made of a refractory material which may not pollute the material in the crucible, for example, the refractory material can be titanium, tungsten, stainless steel or ceramic and so on, which will not be described respectively here.

The driving unit 3 drives the stirring unit 2 to rotate in a driving mode such as mechanical driving, power driving, magnetic force driving and so on, which will not be described respectively here, and optionally, the driving unit 3 may be an electric engine.

In order to improve heating uniformity for the material in the crucible, a rotational speed of the stirring unit 2 is 0-100 rev/min, where the rotational speed of the stirring unit, for example, refers to a speed of the blades 22 rotating around the vertical rod 212. For example, the speed may be 20 rev/min, 35 rev/min, 45V rev/min, 55 rev/min, 60 rev/min, 70 rev/min, 80 rev/min, 90 rev/min, 100 rev/min and so on, which will not be respectively here. The specific rotational speed may be determined by those skilled in the art according to actual needs.

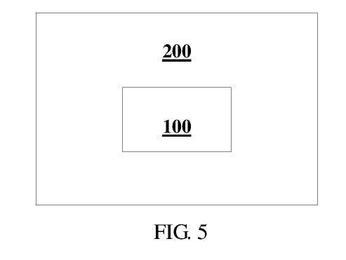

An embodiment of the present invention further provides an evaporation apparatus, comprising the evaporation source device provided by any embodiment described above. Referring to FIG. 5, an evaporation apparatus 200 comprises the evaporation source device 100 described above. Since the evaporation source device may improve the heating uniformity for a material, further increase a material deposition yield, and improve performance of a display device, the evaporation apparatus provided by the embodiment of present invention has good usability.

Although the embodiments of the present invention have been described above in great detail with general descriptions and specific embodiments, on the basis of the embodiments of the present invention, various changes and improvements may be made, which is apparent to those skilled in the art. Therefore, these modifications or improvements without departing from the spirit of the present invention all belong to the protection scope claimed by the present invention.

The present application claims priority of Chinese Patent Application No. 201510300073.7 filed on Jun. 3, 2015, the disclosure of which is incorporated herein by reference in its entirety as part of the present application.

1. An evaporation source device, comprising:
a crucible having an opening, configured for accommodating a material;
a stirring unit, configured for stirring the material in the crucible; and
a driving unit, configured for driving the stirring unit to rotate.

2. The evaporation source device according to claim 1, wherein, the stirring unit includes: a connecting rod and one or more blades, an end of the connecting rod being connected with the driving unit so that the connecting rod may be driven to rotate, and another end of the connecting rod being fixedly connected with the one or more blades.

3. The evaporation source device according to claim 2, wherein, the connecting rod includes a sub connecting rod fixedly connected with the one or more blades.

4. The evaporation source device according to claim 3, wherein, the sub connecting rod is configured to be driven by the driving unit to rotate around an axis of the sub connecting rod.

5. The evaporation source device according to claim 4, wherein, the axis of the sub connecting rod coincides with an axis of the crucible.

6. The evaporation source device according to claim 3, wherein, the sub connecting rod is driven to rotate around an rotation axis intersecting with a bottom of the crucible and passing through the opening of the crucible, and the rotation axis is not intersected with the sub connecting rod.

7. The evaporation source device according to claim 6, wherein, the rotation axis overlaps with an axis of the crucible.

8. The evaporation source device according to claim 2, further comprising: a shielding net, arranged at the opening of the crucible and configured for preventing the material from spilled from the opening of the crucible.

9. The evaporation source device according to claim 4, wherein, the stirring unit further includes: a transmission rod, an end of the transmission rod being connected with the driving unit, and the other end being fixedly connected with a side wall of the shielding net, and the end of the connecting rod being connected with a bottom of the shielding net.

10. The evaporation source device according to claim 2, wherein, the one or more blades and the connecting rod are connected by welding or a bolt.

11. The evaporation source device according to claim 2, wherein, the one or more blades and at least a part of the connecting rod are made of titanium, tungsten, stainless steel or ceramic.

12. The evaporation source device according to claim 1, wherein, the driving unit is a motor.

13. The evaporation source device according to claim 1, wherein, a rotational speed of the stirring unit is 0-100 rev/min.

14. The evaporation source device according to claim 2, wherein, the end of the connecting rod is in rotatable connection with the driving unit.

15. The evaporation source device according to claim 2, wherein, the sub connecting rod of the connecting rod is a vertical rod of straightline shape.

16. The evaporation source device according to claim 2, wherein, a number of one or more blades is greater than or equal to 2.

17. An evaporation apparatus, comprising the evaporation source device according to claim 1.
